(19) United States
(12) Patent Application Publication
(10) Pub. No.: US 2026/0371662 A1
(43) Pub. Date: Nov. 19, 2026

(54) SEMICONDUCTOR DEVICE AND METHOD OF MANUFACTURING SEMICONDUCTOR DEVICE

(71) Applicant: FUJI ELECTRIC CO., LTD., Kawasaki-shi (JP)

(72) Inventors: Shin MIYAMOTO, Matsumoto-city (JP); Yuichi HASHIZUME, Matsumoto-city (JP)

(73) Assignee: FUJI ELECTRIC CO., LTD., Kawasaki-shi (JP)

(21) Appl. No.: 19/635,205

(22) Filed: Mar. 31, 2026

(30) Foreign Application Priority Data
May 13, 2025 (JP) 2025-080704

(51) Int. Cl. H10D 62/10; H10D 30/01; H10D 30/66

(52) U.S. Cl. CPC H10D 62/105; H10D 30/0297; H10D 30/668; H10D 62/115

(57) ABSTRACT

A semiconductor device has a semiconductor substrate having an active region and a termination region surrounding a periphery of the active region, a front electrode provided substantially in the active region, a field insulating film provided in the termination region, and a first polyimide film covering a boundary portion between the front electrode and the field insulating film. The surface roughness of a first side surface of the first polyimide film is smaller than the surface roughness of a second side surface of the first polyimide film and the surface roughness of an upper surface of the first polyimide film, the first side surface being closer to the field insulating film than is the second side surface, and the second side surface is closer to the front electrode than is the first side surface.

### CROSS REFERENCE TO RELATED APPLICATIONS

This application is based upon and claims the benefit of priority of the prior Japanese Patent Application No. 2025-080704, filed on May 13, 2025, the entire contents of which are incorporated herein by reference.

### BACKGROUND OF THE INVENTION

### 1. Field of the Invention

Embodiments of the disclosure relate to a semiconductor device and a method of manufacturing a semiconductor device.

### 2. Description of the Related Art

Conventionally, in order to improve adhesion between a polyimide film and an encapsulation resin, a semiconductor device has been proposed in which unevenness is provided at a surface of the polyimide film to prevent peeling between the polyimide film and the encapsulation resin (for example, refer to Japanese Laid-Open Patent Publication No. 2022-168905 and Japanese Laid-Open Patent Publication No. 2002-270735).

### SUMMARY OF THE INVENTION

According to an embodiment of the present disclosure, a semiconductor device includes: a semiconductor substrate having an active region and a termination region surrounding a periphery of the active region in a plan view; a front electrode provided substantially in the active region; a field insulating film provided in the termination region and adjacent to the front electrode to form a boundary portion therebetween; and a first polyimide film covering the boundary portion between the front electrode and the field insulating film, the first polyimide film having an upper surface, a first side surface, and a second side surface,

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting a structure of a silicon carbide semiconductor device according to a first embodiment.

FIG. 2 is a flowchart of a method of manufacturing the silicon carbide semiconductor device according to the first embodiment.

FIG. 3 is a cross-sectional view of the silicon carbide semiconductor device according to the first embodiment during manufacture.

FIG. 4 is a cross-sectional view depicting another structure of the silicon carbide semiconductor device according to the first embodiment.

FIG. 5 is a cross-sectional view depicting a structure of a silicon carbide semiconductor device according to a second embodiment.

FIG. 6 is a flowchart of a method of manufacturing the silicon carbide semiconductor device according to the second embodiment.

FIG. 7 is a cross-sectional view depicting a structure of a silicon carbide semiconductor device of a comparative example.

FIG. 8 is a cross-sectional view depicting another structure of the silicon carbide semiconductor device of the comparative example.

FIG. 9 is a cross-sectional view depicting another structure of the silicon carbide semiconductor device of the comparative example.

### DETAILED DESCRIPTION OF THE INVENTION

First problems associated with the conventional techniques are discussed. When the unevenness is provided at the entire surface of the polyimide film, peeling between the encapsulation resin and an insulating film penetrates inside the semiconductor device, and the semiconductor device may fail.

Here, an outline of an embodiment of the present disclosure is described. A semiconductor device according to the present disclosure has the following features. The semiconductor device has: a semiconductor substrate having an active region and a termination region surrounding a periphery of the active region in a plan view, a front electrode provided in the active region, a field insulating film provided in the termination region, and a first polyimide film covering a boundary region between the front electrode and the field insulating film. The surface roughness of a first side surface of the first polyimide film is greater than the surface roughness of a second side surface of the first polyimide film and the surface roughness of an upper surface of the first polyimide film, the first side surface being closer to the field insulating film than is the second side surface, which is closer to front electrode than is the first side surface.

According to the above disclosure, when peeling progresses, the adhesion between the polyimide film and the field insulating film is stronger than the adhesion between the polyimide film not subjected to ashing and the encapsulation resin. Thus, the peeling progresses to the first side surface of the polyimide film (side surface relatively closer to the field insulating film) without penetrating inside the semiconductor chip, and the peeling may be controlled to the outside of the semiconductor chip. Thus, it is possible to prevent the semiconductor device from failing in terms of electrical characteristics due to peeling.

Further, the semiconductor device according to the present disclosure, in the disclosure above, has at the upper surface of the first polyimide film, a first portion having a surface roughness greater than a surface roughness of the first side surface of the first polyimide film, and a second portion having a surface roughness smaller than that of the first portion; a boundary between the first portion and the second portion is closer to the first side surface of the first polyimide film than to the second side surface of the first polyimide film.

Further, in the semiconductor device according to the present disclosure, in the disclosure above, the surface roughness (Ra) of the second side surface and the upper surface of the first polyimide film is 5 nm or more but not more than 60 nm.

Further, in the semiconductor device according to the present disclosure, in the disclosure above, the surface roughness (Ra) of the first side surface of the first polyimide film is greater than 0 nm but not more than 3 nm.

Further, in the semiconductor device according to the present disclosure, in the disclosure above, a distance from the first side surface to the second side surface of the first polyimide film is 100 μm or more but not more than 800 μm.

Further, in the semiconductor device according to the present disclosure, in the disclosure above, the field insulating film has two layers including a thermal oxide film and a deposited insulating film.

Further, the semiconductor device according to the present disclosure, in the disclosure above, further has a second polyimide film covering the first side surface of the first polyimide film. A surface roughness of the second polyimide film is smaller than the surface roughness of the upper surface of the first polyimide film.

Further, the semiconductor device according to the present disclosure, in the disclosure above, further includes a first semiconductor layer of a first conductivity type, provided at a front surface of the semiconductor substrate and having a dopant concentration lower than that of the semiconductor substrate; first semiconductor regions of a second conductivity type, selectively provided in the first semiconductor layer, at a first surface thereof opposite to a second surface thereof facing the semiconductor substrate, the first semiconductor regions being in contact with the front electrode; and a back electrode provided at a back surface of the semiconductor substrate.

Further, the semiconductor device according to the present disclosure, in the disclosure above, further includes a first semiconductor layer of a first conductivity type, provided at a front surface of the semiconductor substrate and having a dopant concentration lower than that of the semiconductor substrate; a second semiconductor layer of a second conductivity type, provided at a first surface of the first semiconductor layer, opposite to a second surface thereof facing the semiconductor substrate; first semiconductor regions of the first conductivity type, selectively provided in the second semiconductor layer, at a first surface thereof opposite to a second surface thereof facing the semiconductor substrate; a gate electrode provided on at least a part of a surface of the second semiconductor layer, between the first semiconductor regions and the first semiconductor layer via a gate insulating film; and a back electrode provided at a back surface of the semiconductor substrate. The front electrode is provided on surfaces of the second semiconductor layer and the first semiconductor regions.

A method of manufacturing a semiconductor device according to the present disclosure has the following features. The method is a method of manufacturing a semiconductor device having a semiconductor substrate having an active region and a termination region surrounding a periphery of the active region in a plan view. First, a first process of forming a field insulating film in the termination region is performed. Next, a second process of forming a front electrode in the active region is performed. Next, a third process of forming a first polyimide film covering a boundary between the front electrode and the field insulating film is performed, the first polyimide film having a first side surface and a second side surface opposite to each other, the first side surface being closer to the field insulating film than is the second side surface, and the second side surface being closer to the front electrode than is the first side surface. Next, a fourth process of forming a resist covering the first side surface of the first polyimide film is performed. Next, a fifth process of performing ashing for roughening a surface of the first polyimide film is performed.

Further, in method of manufacturing the semiconductor device according to the present disclosure, in the disclosure above, the fifth process includes performing the ashing using oxygen plasma.

Further, the method of manufacturing the semiconductor device according to the present disclosure, in the disclosure above, further includes a sixth process of omitting the fourth process and forming a second polyimide film covering the first side surface of the first polyimide film after the fifth process.

Further, in the method of manufacturing the semiconductor device according to the present disclosure, in the disclosure above, the sixth process includes forming the second polyimide film using a discharge method.

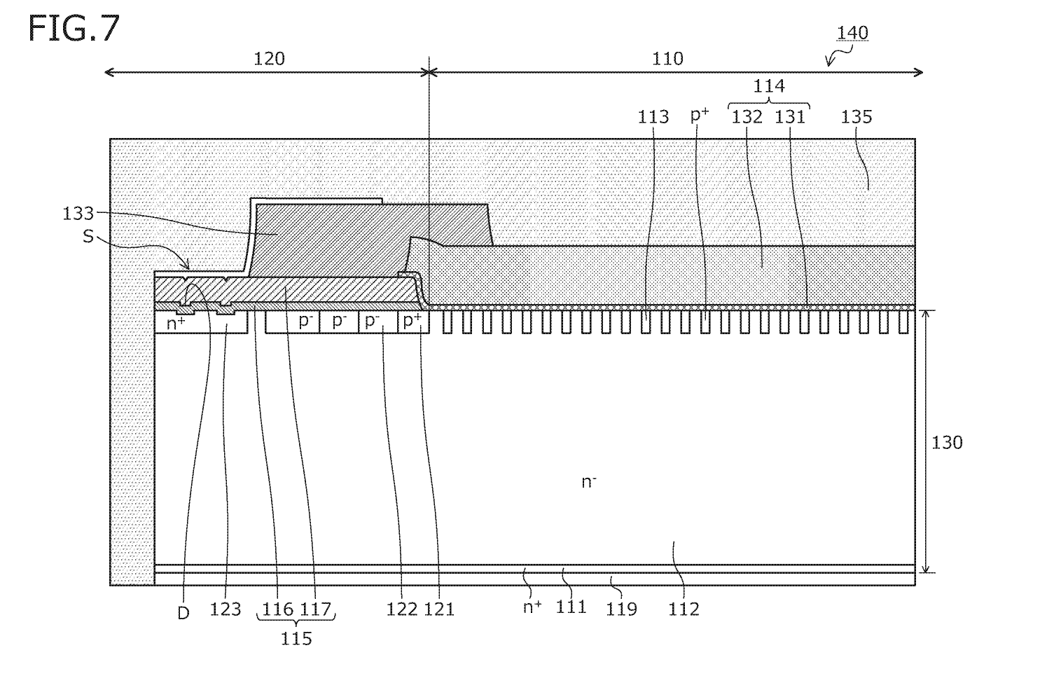

Here, findings underlying the present disclosure are discussed. First, problems of the semiconductor device of the comparative example will be described. FIG. 7 is a cross-sectional view depicting a structure of a silicon carbide semiconductor device of a comparative example. FIG. 7 depicts a Schottky barrier diode (SBD) as a silicon carbide semiconductor device 140 of the comparative example.

The silicon carbide semiconductor device 140 of the comparative example depicted in FIG. 7 includes an active region 110 in which a device structure is formed and through which a current flows during an on-state, and an edge termination region 120 that surrounds a periphery of the active region 110 in a plan view and sustains a breakdown voltage.

The silicon carbide semiconductor device 140 is a vertical silicon carbide diode having a JBS structure in which an SBD structure by a Schottky junction between an n⁻-type drift region 112 and a titanium film 131 constituting a front electrode 114 and pn junctions between p⁺-type regions 113 and the n⁻-type drift region 112 are mixed. A nickel silicide film (not depicted) may be provided on the p⁺-type regions 113 as a lowermost layer of the front electrode 114.

The Schottky junction of the silicon carbide semiconductor device 140 of the comparative example is formed by the n⁻-type drift region 112 exposed at the front surface of the semiconductor substrate 130 and the front electrode 114 including the titanium film 131 and an aluminum alloy film 132 provided on the front surface of the semiconductor substrate 130. The semiconductor substrate 130 is an epitaxial substrate in which an n⁻-type epitaxial layer serving as the n⁻-type drift region 112 is stacked on a front surface of an n⁺-type starting substrate 111 containing silicon carbide. The n⁺-type starting substrate 111 is an n⁺-type cathode region. A back electrode 119 is provided at an entire back surface of the semiconductor substrate 130 and is electrically connected to the n⁺-type starting substrate 111.

In the edge termination region 120, the n⁻-type drift region 112 is exposed, and a voltage withstanding structure such as a field limiting ring (FLR) 121 and p⁻-type regions 122 constituting a JTE structure are provided. Further, an n⁺-type region constituting a channel stopper is disposed outside the voltage withstanding structure. A field insulating film 115 including a thermal oxide film 116 and a deposited oxide film 117 is provided at the surface of the voltage withstanding structure and an n⁺-type region 123, and a polyimide film 133 is provided as a protective film at the surface of the silicon carbide semiconductor device 140. Further, the field insulating film 115 on the n⁺-type region has a step D. The described silicon carbide semiconductor device 140 is encapsulated in a case (not depicted) by an encapsulation resin 135.

In the edge termination region 120, since the polyimide film 133 cannot be formed up to the scribe surface (chip end), the field insulating film 115 not covered by the polyimide film 133 is in contact with the encapsulation resin 135.

The adhesion between the field insulating film 115 and the encapsulation resin 135 is poor. For this reason, when the silicon carbide semiconductor device 140 is exposed to thermal shock, peeling S occurs due to expansion and contraction stress of the encapsulation resin 135, the encapsulation resin 135 peels off from the field insulating film 115, the peeling S progresses, the polyimide film 133 and the encapsulation resin 135 peel off, and there is a problem in that a failure of the silicon carbide semiconductor device 140 occurs.

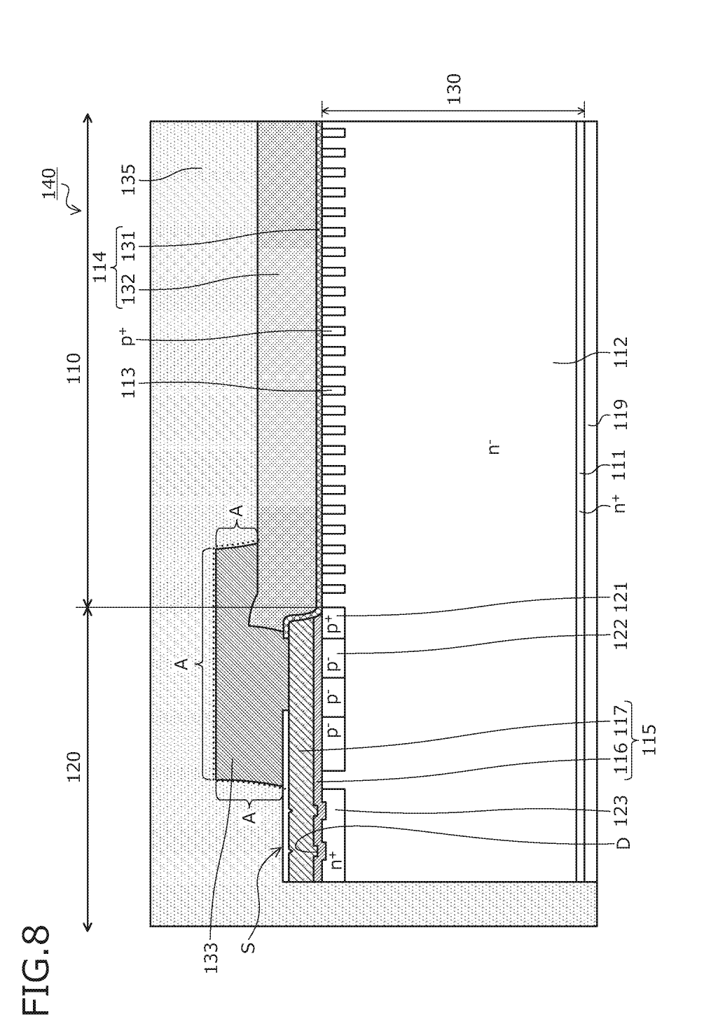

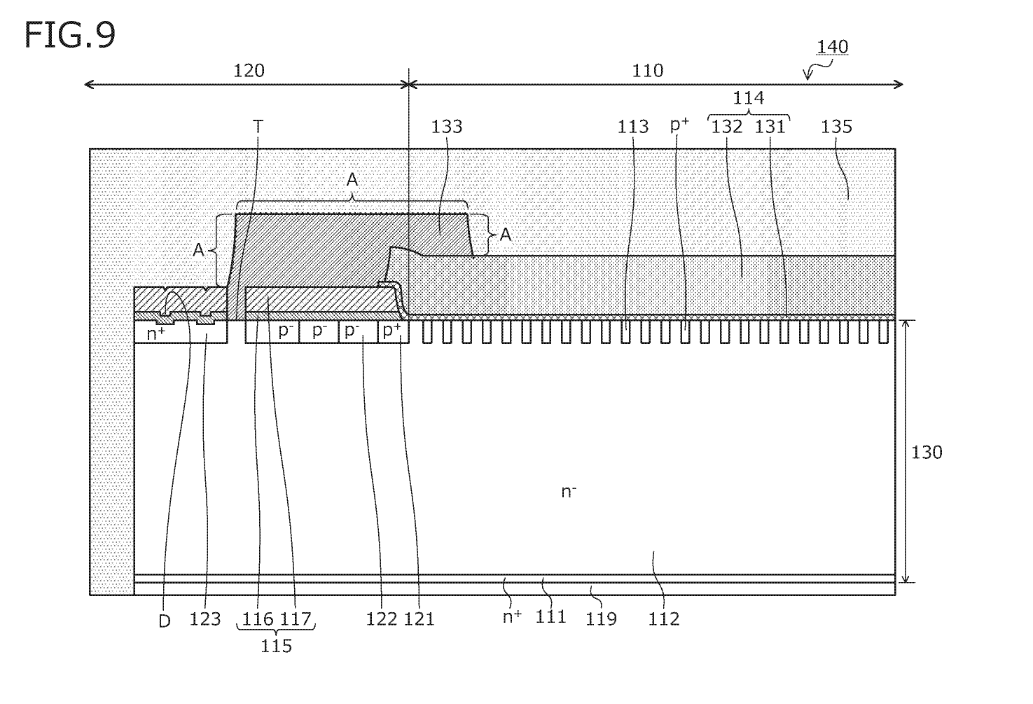

FIGS. 8 and 9 are cross-sectional views depicting other structures of the silicon carbide semiconductor device of the comparative example. In order to solve the above problems, another structure of the silicon carbide semiconductor device has been proposed. In the structure depicted in FIG. 8, an ashing region A having a roughened surface is formed on the entire surface of the polyimide film 133 which is an insulating protective film on the chip surface, and the adhesion between the polyimide film 133 and the encapsulation resin 135 is improved by roughening the surface.

However, in this structure, as depicted in FIG. 8, the polyimide film 133 is affected by the expansion and contraction of the encapsulation resin 135 due to the improved adhesion, and the peeling S changes so as to penetrate inside the chip. As a result, the polyimide film 133 may peel off from the chip, resulting in a more serious failure.

For this reason, in the structure depicted FIG. 9, as a further countermeasure, a substantially vertical notch T is formed in the field insulating film 115 under the polyimide film 133 to rotate the direction in which the peeling S processes by 90°, thereby preventing the peeling from progressing insides the chip.

However, even in the structure depicted in FIG. 9, the peeling S is allowed to progress inside the chip, which is not preferable in terms of reliability. It is important to stop the progress of the peeling S outside the chip. Therefore, the present disclosure provides a semiconductor device and a method of manufacturing the semiconductor device capable of preventing development of peeling between the encapsulation resin 135 and the field insulating film 115 outside the semiconductor chip and preventing a failure due to the peeling. The outside of the semiconductor chip is a portion where the encapsulation resin 135 is provided outside the polyimide film 133, the field insulating film 115, and the front electrode 114.

Hereinafter, embodiments of a semiconductor device and a method of manufacturing a semiconductor device according to the present disclosure and solving the problems of the semiconductor device of the comparative example described above will be described in detail with reference to the accompanying drawings. In the present specification and the accompanying drawings, layers and regions prefixed with n or p mean that majority carriers are electrons or holes, respectively. Further, + and − appended to n and p mean that the dopant concentration is higher and lower, respectively, than layers and regions without + and −. In the following description of the embodiments and the accompanying drawings, components that are the same are denoted by the same reference numerals, and redundant description thereof will be omitted. The term “the same” or “equal” preferably may be within 5% or less in consideration of manufacturing variations.

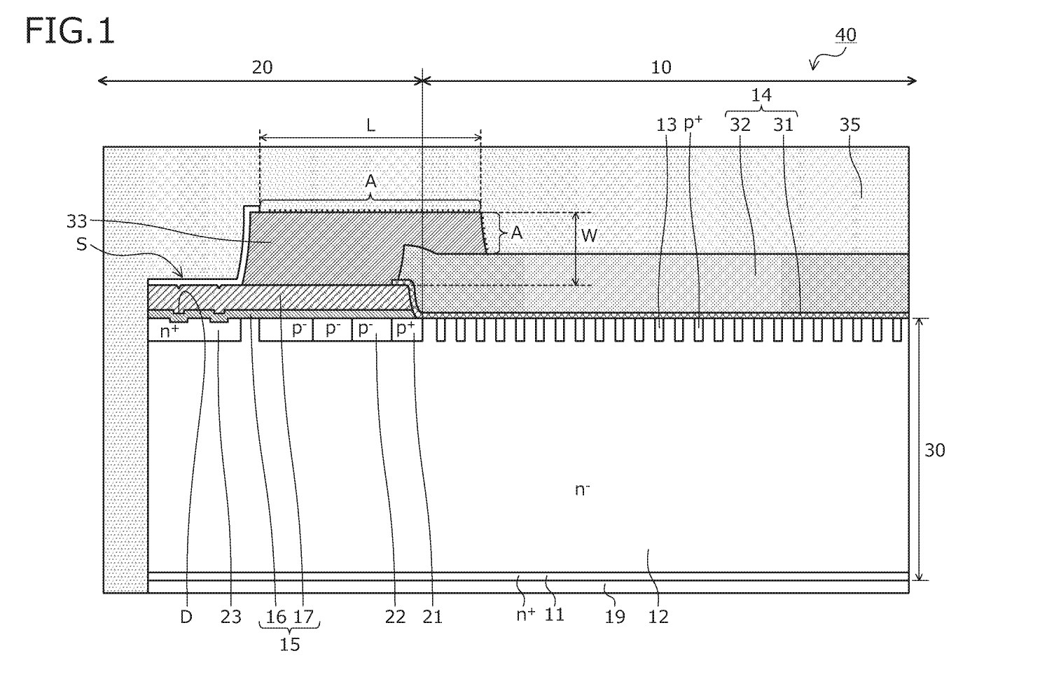

A semiconductor device according to the present disclosure contains a wide band gap semiconductor. In a first embodiment, a silicon carbide semiconductor device 40 fabricated (manufactured) using, for example, silicon carbide (SiC) as a wide band gap semiconductor will be described taking a Schottky barrier diode as an example. FIG. 1 is a cross-sectional view depicting a structure of a silicon carbide semiconductor device according to the first embodiment.

A silicon carbide semiconductor device 40 according to the first embodiment is a silicon carbide diode having, in a semiconductor substrate 30, at a front surface (first main surface) thereof, in the active region 10, a JBS structure in which an SBD structure configured by a Schottky junction between a front electrode 14 and an n⁻-type drift region (first semiconductor layer of a first conductivity type) 12 and a pn diode configured by pn junctions between p⁺-type regions (first semiconductor regions of a second conductivity type) 13 and the n⁻-type drift region 12 are mixed.

The semiconductor substrate 30 is an epitaxial substrate in which an n⁻-type epitaxial layer constituting the n⁻-type drift region 12 is stacked on a front surface of an n⁺-type starting substrate 11 containing silicon carbide. The n⁺-type starting substrate 11 constitutes an n⁺-type cathode region. The semiconductor substrate 30, has as the front surface, a main surface having the n⁻-type drift region 12 (a front surface of the n⁻-type epitaxial layer constituting the n⁻-type drift region 12), and as a back surface, a main surface having the n⁺-type starting substrate 11 (back surface of the n⁺-type starting substrate 11). In the active region 10, a front electrode 14 functioning as an anode electrode is provided along the front surface of the semiconductor substrate 30. A back electrode 19 is provided at the entire back surface of the semiconductor substrate 30 (the back surface of the n⁺-type starting substrate 11) and is electrically connected to the n⁺-type starting substrate 11.

The active region 10 is a region through which a current flows when the silicon carbide diode is in an on-state. The active region 10 has, for example, a substantially rectangular planar shape in a plan view and is disposed substantially at a center of the semiconductor substrate 30. The edge termination region 20 is a region between the active region 10 and an end portion of the semiconductor substrate 30, and surrounds the periphery of the active region 10. The edge termination region 20 is a region of the n⁻-type drift region 12 that relaxes the electric field of a front side of the semiconductor substrate 30 and maintains a breakdown voltage. The breakdown voltage is a voltage limit at which a device does not malfunction or break down.

The front electrode 14 has a stacked structure in which a titanium film 31 and an aluminum alloy film (metal electrode film containing aluminum) 32 are stacked in this order. In addition, the front electrode 14 may have a lowermost nickel silicide (NiSi) film (not depicted) selectively provided between the front surface of the semiconductor substrate 30 and the titanium film 31. The nickel silicide film is an ohmic electrode in ohmic contact with the p⁺-type regions 13. The nickel silicide film has a function of increasing the amount (extraction amount) of a surge current that is drawn from within the semiconductor substrate 30 to the front electrode 14 to thereby improve surge current resistance, the surge current being generated in the semiconductor substrate 30 when a surge voltage is applied and flowing in a forward direction.

In the edge termination region 20, an FLR 21, one or more p⁻-type regions 22 (here, three) configuring the JTE structure, and an n⁺-type region 23 constituting an n⁺-type channel stopper are selectively provided in the semiconductor substrate 30, at the front surface thereof. The JTE structure is a voltage withstanding structure having a substantially rectangular shape in a plan view and in which multiple p-type regions having different dopant concentrations surround the periphery of the active region 10 in descending order of dopant concentration in a direction from the active region 10 (center side of the semiconductor substrate 30) to the edge termination region 20 (end portion side of the semiconductor substrate 30).

The field limiting ring (FLR) 21 is disposed in the edge termination region 20, closer to the active region 10 than to a chip end. The FLR 21 is a p⁺-type region that surrounds the periphery of the active region 10 in a substantially rectangular shape in a plan view and extends outward from the edge termination region 20 to be in contact with the p⁻-type regions 22. The FLR 21 may be in contact with the p⁺-type regions 13 in the longitudinal direction in which the p⁺-type regions 13 extend in a linear shape.

The front electrode 14 is provided at the front surface of the semiconductor substrate 30 in the active region 10. The front electrode 14 is in contact with the n⁻-type drift region 12 and the p⁺-type regions 13, and is electrically connected to the n⁻-type drift region 12, the p⁺-type regions 13, and the FLR 21. An end portion of the front electrode 14 extends on a field insulating film 15 described later. On the front surface of the semiconductor substrate 30, a polyimide film (first polyimide film) 33 covering a boundary portion between the front electrode 14 and the field insulating film 15 to be described later is annularly provided. The polyimide film 33 functions as a protective film that protects the device structure at the front surface of the semiconductor substrate 30 and the front electrode 14.

In the edge termination region 20, the front surface of the semiconductor substrate 30 is covered with the field insulating film 15. The field insulating film 15 is annularly provided so as to cover a chip end portion side of the FLR 21, the chip end portion side thereof facing the chip end. The field insulating film 15 may be, for example, a stacked film in which a thermal oxide film 16 and a deposited oxide film 17 are sequentially stacked. The thermal oxide film 16 may improve adhesion between the semiconductor substrate 30 and the field insulating film 15. Since the field insulating film 15 includes the deposited oxide film 17, the field insulating film 15 may be formed in a shorter time than when the entire field insulating film 15 is the thermal oxide film 16.

In the first embodiment, the step D is provided in the field insulating film 15 on the n⁺-type region 23. The step D increases the contact area between the n⁺-type region 23 and the field insulating film 15, thereby preventing the field insulating film 15 from peeling off from the n⁺-type region 23.

In the edge termination region 20, since the polyimide film 33 cannot be formed up to the scribe surface (chip end), the polyimide film 33 covers up to the middle of the field insulating film 15, and the field insulating film 15 is exposed at the chip end portion. The chip end is a scribed surface at an end of the semiconductor chip, and the chip end portion is a region of the semiconductor chip in which at least the n⁺-type region 23 is provided.

From the comparative example depicted in FIGS. 7 and 8 described above, it is considered that the adhesive force between the semiconductor chip and the encapsulation resin 35 in descending order of strength is as follows.
Adhesion: strong Adhesive force between polyimide film 33 (with ashing region A) and encapsulation resin 35
Adhesion: medium Adhesive force between polyimide film 33 and field insulating film 15
Adhesion: weak Adhesion between polyimide film 33 (without ashing region A) and encapsulation resin 35

Therefore, to prevent the peeling of the encapsulation resin 35, it is preferable to use the adhesion between the polyimide film 33 (having the ashing region A) having the strongest adhesion and the encapsulation resin 35. However, as in the comparative example depicted in FIG. 8, since the adhesive force is stronger than the adhesive force between the polyimide film 33 and the field insulating film 15, the peeling S penetrates inside the semiconductor chip. Further, from the perspective of reliability, it is preferable to prevent the development of the peeling not inside but outside the semiconductor chip.

In the comparative example depicted in FIG. 8, the starting point from which the encapsulation resin 135 peels is the end portion (inclined portion) of the polyimide film 133. Therefore, in the first embodiment, the adhesion of the side surface of the polyimide film 33, above the field insulating film 15 (facing the chip end) is intentionally not improved, and the advancement direction of the peeling S is controlled to the outward direction of the semiconductor chip, along the surface of the inclined portion of the polyimide film 33. Therefore, in the first embodiment, as depicted in FIG. 1, the ashing region A whose surface is roughened by ashing or the like is provided only on the upper surface and a side surface (second side surface) of the polyimide film 33, the second side surface thereof being closer to the front electrode 14 than is a first side surface of the polyimide film 33. On the other hand, the ashing region A is not provided on the other side surface (first side surface) of the polyimide film 33, the first side surface being closer to the field insulating film 15 than is the second side surface of the polyimide film 33. Therefore, in the first embodiment, the surface roughness (Ra) of the polyimide film 33, at the first side surface thereof is smaller than the surface roughness (Ra) at the second side surface thereof and the surface roughness (Ra) of the upper surface thereof. A flat portion that is not ashed may be provided at the upper surface of the polyimide film 33, closer to the field insulating film 15 than to the front electrode. The surface roughness (Ra) of the flat portion of the upper surface of the polyimide film 33 is smaller than the surface roughness (Ra) of the ashing region A of the upper surface of the polyimide film 33. At the upper surface of the polyimide film 33, the boundary between the flat portion and the ashing region A is closer to the first side surface (side surface relatively closer to the field insulating film 15) of the polyimide film 33 than to the second side surface (side surface relatively closer to the front electrode 14).

For example, the surface roughness (Ra) of the ashing region A having a roughened surface is 5 nm or more but not more than 60 nm and preferably, may be 8 nm or more but not more than 30 nm. By setting the surface roughness (Ra) in this range, the adhesion between the polyimide film 33 (with the ashing region A) and the encapsulation resin 35 may be made stronger than the adhesion between the polyimide film 33 and the field insulating film 15. On the other hand, the surface roughness (Ra) of the flat portion of the polyimide film 33 (without the ashing region A) whose surface is not roughened is more than 0 nm but not more than 3 nm and preferably, may be not more than 2 nm.

As described above, the adhesion between the polyimide film 33 and the field insulating film 15 is stronger than the adhesion between the polyimide film 33 (without the ashing region A) and the encapsulation resin 35. Therefore, in the first embodiment, when the peeling S advances, the peeling S advances to the first side surface (side surface relatively closer to the field insulating film 15) of the polyimide film 33 without penetrating inside the semiconductor chip as depicted in FIG. 1. Further, the advancement of the peeling S is stopped by the adhesion of the ashing region A on the polyimide film 33. As described above, in the first embodiment, by not providing the ashing region A on the first side surface of the polyimide film 33, it is possible to control the advancement direction of the peeling S to the outside of the semiconductor chip.

In the first embodiment, the thickness W of the polyimide film 33 may be preferably 9 μm or more but not more than 21 μm. Further, the length L of the ashing region A on the upper surface of the polyimide film 33 may be preferably 100 μm or more but not more than 800 μm. A length L of the ashing region A is a distance from the first side surface of the polyimide film 33 to the second side surface thereof. The entire upper surface of the polyimide film 33 may be free of the ashing region A. In this case, the upper surface of the polyimide film 33 has a first portion having a surface roughness greater than that of the first side surface of the polyimide film 33 and a second portion having a surface roughness smaller than that of the first portion having the surface roughness greater than that of the first side surface of the polyimide film 33. Preferably, a boundary between the portion with the larger surface roughness and the portion with the smaller surface roughness may be closer to the first side surface of the polyimide film 33 than to the second side surface thereof.

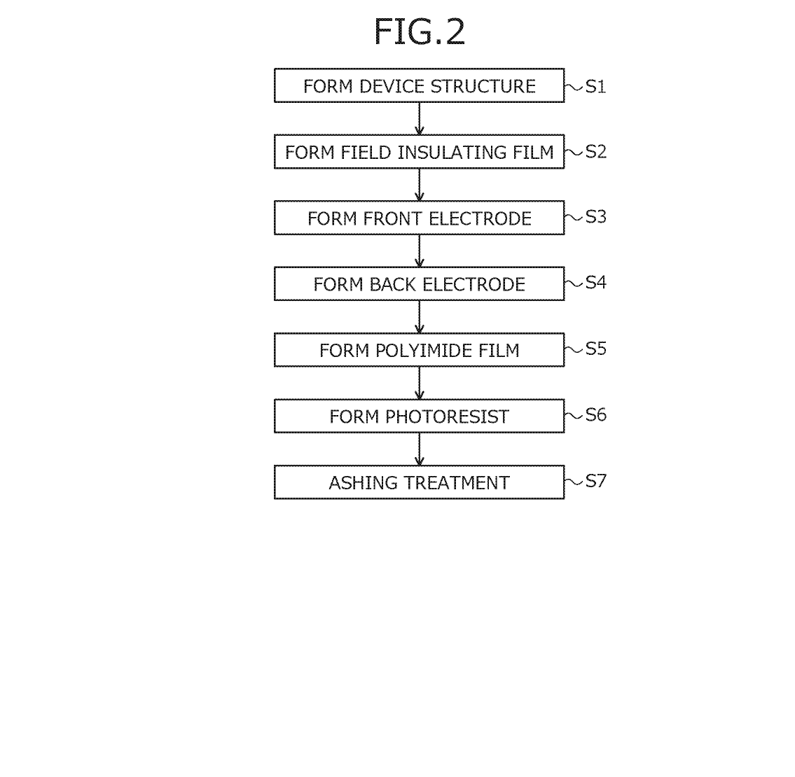

The silicon carbide semiconductor device according to the first embodiment may be manufactured by the following method. FIG. 2 is a flowchart of a method of manufacturing the silicon carbide semiconductor device according to the first embodiment.

In the method of manufacturing the silicon carbide semiconductor device 40 according to the first embodiment, first, a device structure is formed as follows (step S1). For example, as the n⁺-type starting substrate (semiconductor wafer) 11, for example, a four-layer periodic hexagonal silicon carbide (4H-SiC) substrate doped with nitrogen (N) of about 5×10¹⁸/cm³ is prepared. Next, on the front surface of the n⁺-type starting substrate 11, an n⁻-type epitaxial layer doped with about 1.8×10¹⁶/cm³ of nitrogen and constituting the n⁻-type drift region 12 is grown, thereby forming the semiconductor substrate 30.

Next, the one or more p⁺-type regions 13 constituting the JBS structure and the FLR 21 are selectively formed in the semiconductor substrate 30, at the front surface thereof, in the active region 10 by photolithography and ion implantation of a p-type impurity such as aluminum. The p⁻-type regions 22 and the n⁺-type region 23 are also formed in the same manner. Next, after the entire front surface of the semiconductor substrate 30 is covered and protected with, for example, a carbon (C) protective film, the ion-implanted dopants are activated by a heat treatment.

Next, the field insulating film 15 is formed on the entire front surface of the semiconductor substrate 30 (step S2: first process). Next, etching is performed using a resist film as a mask to form contact holes penetrating through the field insulating film 15 in the depth direction. Next, a titanium film 31 is formed on an entire surface from the surface of the field insulating film 15 to the front surface of the semiconductor substrate 30 in the contact holes by, for example, physical vapor deposition (PVD) such as sputtering. Next, the titanium film 31 is left only in the contact holes by photolithography and etching.

Next, the titanium film 31 is sintered by a heat treatment at a temperature of, for example, about 500 degrees C, for about 10 minutes. Next, an aluminum alloy film having a thickness of, for example, about 5 μm is formed on an entire surface from the surface of the titanium film 31 to the surface of the field insulating film 15 by a physical vapor deposition method such as sputtering. Next, the aluminum alloy film is selectively removed by photolithography and etching, and the aluminum alloy film 32 is left on the surface of the titanium film 31, thereby forming the front electrode 14 (step S3: second process).

Next, nickel or titanium is deposited on the entire back surface of the semiconductor substrate 30 (the back surface of the n⁺-type starting substrate 11) by a physical vapor deposition method such as sputtering, for example, and then the back electrode 19 is formed by laser annealing (step S4).

Thereafter, a polyimide is applied as a surface passivation film by, for example, spin coating, patterned by photolithography, and heat-treated (cured) to form the polyimide film 33 (step S5: third process).

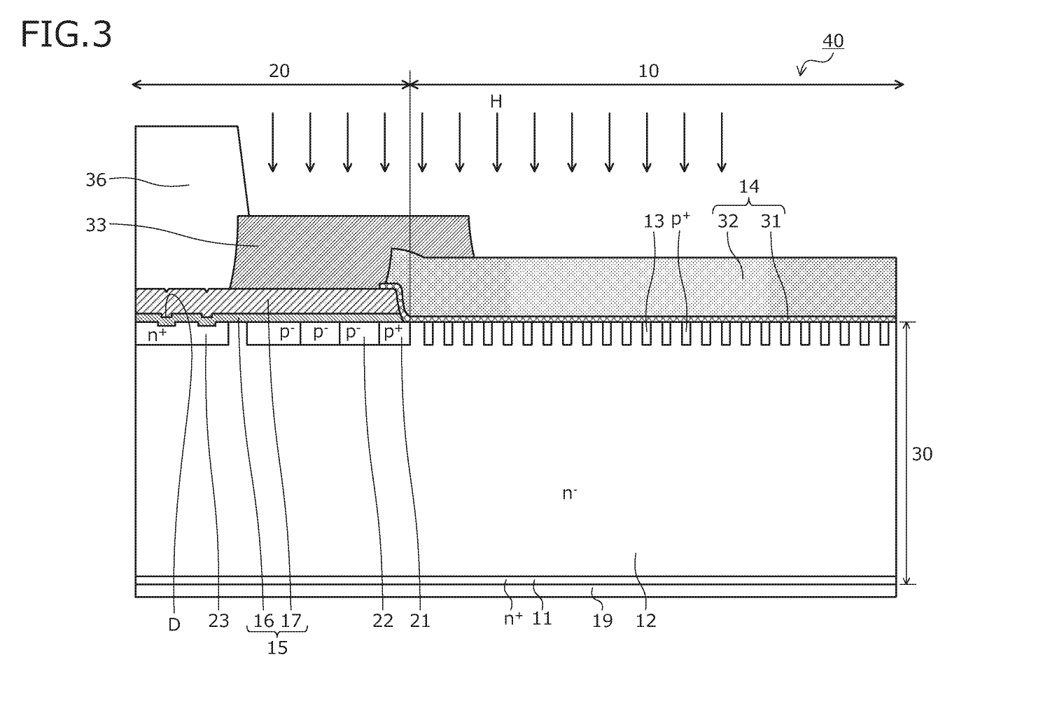

Next, an ashing process is performed on the polyimide film 33. FIG. 3 is a cross-sectional view of the silicon carbide semiconductor device according to the first embodiment during manufacture. As depicted in FIG. 3, first, the second side surface (inclined portion) of the polyimide film 33 is covered with a photoresist 36 (step S6: fourth process). In this state, ashing treatment such as irradiation with oxygen plasma H is performed (step S7: fifth process). As a result, the upper surface and the first side surface of the polyimide film 33 are roughened, and the ashing region A is formed. The second side surface of the polyimide film 33 is not roughened, and the ashing region A is not formed. Thereafter, the photoresist 36 is removed.

Thereafter, the protective film on the front surface of the semiconductor substrate 30 is removed and then, the semiconductor substrate 30 is diced (cut) into individual chips, thereby completing the silicon carbide semiconductor device 40 of the first embodiment.

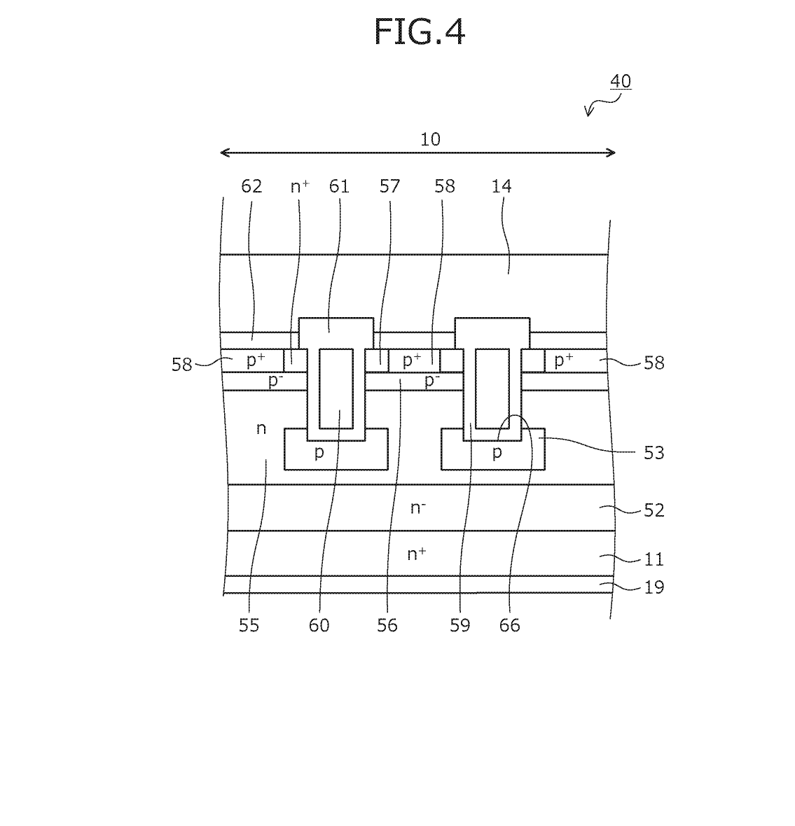

Although the Schottky barrier diode has been described as the silicon carbide semiconductor device 40 according to the first embodiment, the silicon carbide semiconductor device 40 according to the first embodiment may also be applied to a metal oxide semiconductor field effect transistor (MOSFET). FIG. 4 is a cross-sectional view depicting another structure of the silicon carbide semiconductor device according to the first embodiment. As the other structure, a trench MOSFET is depicted. Since the edge termination region 20 is the same as that of the Schottky barrier diode depicted in FIG. 1, only the active region 10 is depicted.

As depicted in FIG. 4, in the trench-type MOSFET according to the first embodiment, an n⁻-type drift layer (first semiconductor layer of the first conductivity type) 52 is deposited on a first main surface (front surface) of the n⁺-type starting substrate 11, for example, a (0001) plane (Si plane).

The n⁺-type starting substrate 11 is a silicon carbide single-crystal substrate. The n⁻-type drift layer 52 has a dopant concentration lower than that of the n⁺-type starting substrate 11, and is, for example, a low-concentration n-type drift layer. An n-type high-concentration region 55 may be provided at a first surface of the n⁻-type drift layer 52, opposite to a second surface thereof facing the n⁺-type starting substrate 11. The n-type high-concentration region 55 is a high-concentration n-type layer having a dopant concentration lower than that of the n⁺-type starting substrate 11 and higher than that of the n⁻-type drift layer 52.

A p⁻-type base layer (second semiconductor layer of the second conductivity type) 56 is provided at a first surface of the n⁻-type drift layer 52 (the n-type high-concentration region 55 in a case where the n-type high-concentration region 55 is provided, hereinafter simply “(55)”), opposite to a second surface thereof facing the n⁺-type starting substrate 11. Hereinafter, the n⁺-type starting substrate 11, the n⁻-type drift layer 52, the n-type high-concentration region 55, and the p⁻-type base layer 56 are collectively referred to as a silicon carbide semiconductor substrate. In the p⁻-type base layer 56, n⁺-type source regions (first semiconductor regions of the first conductivity type) 57 are selectively provided. In the p⁻-type base layer 56, p⁺-type contact regions 58 are selectively provided.

A drain electrode constituting the back electrode 19 is provided at the second main surface (back surface, that is, a back surface of the silicon carbide semiconductor substrate) of the n⁺-type starting substrate 11.

A trench structure is formed in the silicon carbide semiconductor substrate, at the first main surface (surface having the p⁻-type base layer 56) thereof. Specifically, trenches 66 penetrate through the p⁻-type base layer 56 from a first surface (the first main surface of the silicon carbide semiconductor substrate) of the p⁻-type base layer 56, opposite to a second surface thereof facing the n⁺-type starting substrate 11, and reach the n⁻-type drift layer 52 (55). The trenches 66 are provided in a stripe-like shapes. Gate insulating films 59 are formed along the inner wall of the trenches 66, at the bottom and sidewalls of the trenches 66, and gate electrodes 60 are formed on the gate insulating films 59 in the trenches 66. The gate electrodes 60 are insulated from the n⁻-type drift layer 52 (55) and the p⁻-type base layer 56 by the gate insulating films 59. A part of each of the gate electrodes 60 may protrude from a top (side facing ohmic electrodes 62 described later) of the trenches 66 in a direction to the ohmic electrodes 62.

First p-type base regions 53 are provided respectively at positions facing the bottoms of the trenches 66 in the depth direction. A width of each of the first p-type base regions 53 is equal to or wider than a width of each of the trenches 66. The bottoms of the trenches 66 may reach the first p-type base regions 53 or may be located in the n⁻-type drift layer 52 (55), between the p⁻-type base layer 56 and the first p-type base regions 53. The first p-type base regions 53 are doped with, for example, aluminum (Al).

An interlayer insulating film 61 is provided at the entire front surface of the silicon carbide base so as to cover the gate electrodes 60 embedded in the trenches 66. The interlayer insulating film 61 contains, for example, a high temperature oxide (HTO) film and borophosphosilicate glass (BPSG). The ohmic electrodes (front electrode) 62 are in ohmic contact with the n⁺-type source regions 57 and the p⁺-type contact regions 58 via contact holes opened in the interlayer insulating film 61. The ohmic electrodes 62 are electrically insulated from the gate electrodes 60 by the interlayer insulating film 61. The front electrode 14 is provided on the ohmic electrodes 62. The ohmic electrodes 62 and the front electrode 14 may be a single layer, or stacked layers of different materials.

In the active region 10 depicted in FIG. 4, while two trench MOS structures are depicted, further trench MOS (insulated gate containing metal-oxide-semiconductor) structures may be disposed in parallel.

As described above, according to the first embodiment, the ashing region is provided at the upper surface and the second side surface (relatively closer to the front electrode) of the polyimide film, and the ashing region is not provided at the first side surface (side surface relatively closer to the field insulating film) of the polyimide film. Thus, when peeling advances, the adhesion between the polyimide film and the field insulating film is stronger than the adhesion between the polyimide film not subjected to ashing and the encapsulation resin. Therefore, the peeling advances to the first side surface (side surface relatively closer to the field insulating film) of the polyimide film without penetrating inside the semiconductor chip, and the peeling may be controlled to the outside of the semiconductor chip. Therefore, it is possible to prevent the semiconductor device from failing in terms of electrical characteristics due to peeling.

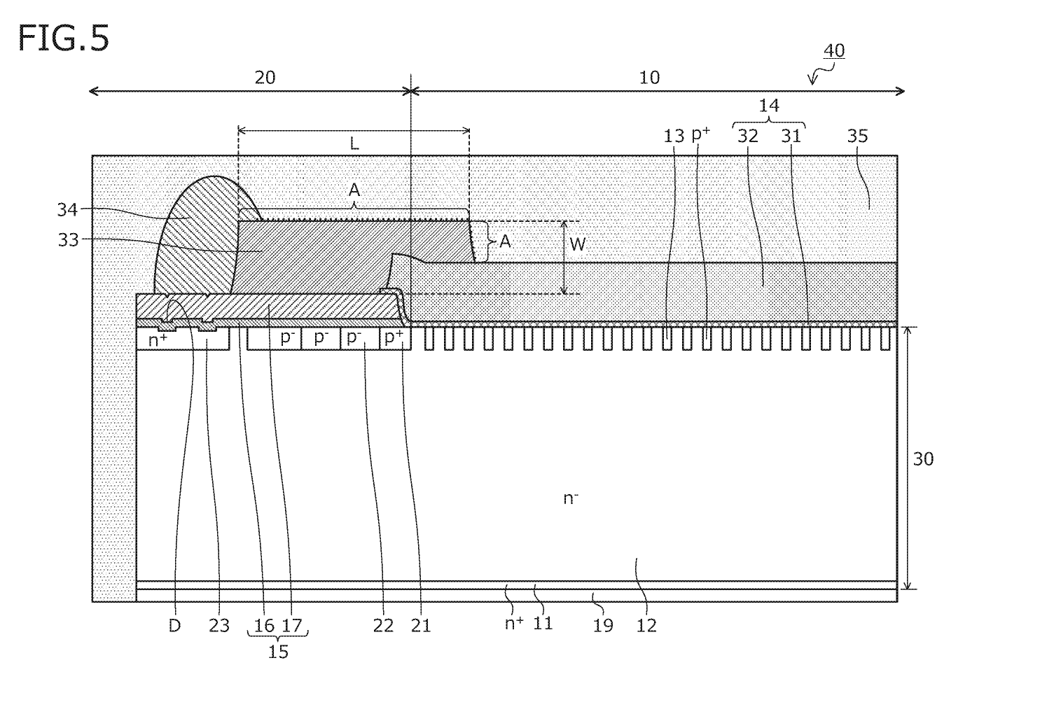

Next, a second embodiment will be described. FIG. 5 is a cross-sectional view depicting a structure of a silicon carbide semiconductor device according to the second embodiment. The second embodiment differs from the first embodiment in that a second polyimide film 34 covering the first side surface (side surface relatively closer to the field insulating film 15) of the polyimide film 33 is provided.

The ashing region A is not provided in the second polyimide film 34 of the second embodiment. Since the entire surface of the polyimide film 33 is the ashing region A, the surface roughness (Ra) of the second polyimide film 34 is smaller than the surface roughness (Ra) of the upper surface of the polyimide film 33. Therefore, the adhesion between the second polyimide film 34 and the encapsulation resin 35 is weaker than the adhesion between the second polyimide film 34 and the field insulating film 15, and the adhesion between the polyimide film 33 and the encapsulation resin 35 is stronger than the adhesion between the polyimide film 33 and the field insulating film 15. Therefore, also in the second embodiment, when peeling (not depicted) advances, the peeling advances in a direction to an interface between the second polyimide film 34 and the encapsulation resin 35 without penetrating inside the semiconductor chip. Further, the advancement of the peeling is stopped by the adhesion of the ashing region A on the polyimide film 33. As described above, in the second embodiment, by providing the second polyimide film 34 covering the first side surface (side surface relatively closer to the field insulating film 15) of the polyimide film 33, it is possible to control the advancement direction of the peeling to the outside of the semiconductor chip.

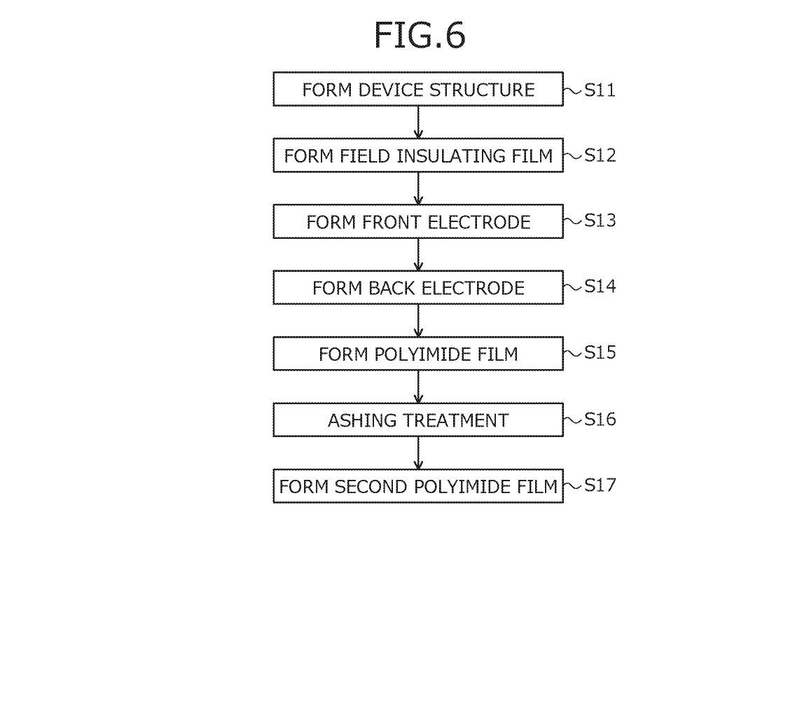

FIG. 6 is a flowchart of a method of manufacturing the silicon carbide semiconductor device according to the second embodiment. In the second embodiment, the ashing process differs from that in the first embodiment. In the second embodiment, as in the first embodiment, a device structure is formed (step S11), and the field insulating film 15 is formed (step S12: first process). Next, the front electrode and the back electrode are formed (step S13: second process, step S14). Thereafter, the polyimide film 33 is formed (step S15: third process).

Next, the polyimide film 33 is ashed (step S16: fifth process). In the second embodiment, the ashing is performed without forming the photoresist 36. Therefore, the entire surface of the polyimide film 33 is roughened, and the ashing region A is formed at the entire surface of the polyimide film 33. Thereafter, the second polyimide film 34 that covers the first side surface (side surface relatively closer to the field insulating film 20) of the polyimide film 33 is formed (step S17: sixth process). Similar to the polyimide film 33, the second polyimide film 34 may be applied by spin coating or may be ejected by an ejection method such as an ink-jet method. Thereafter, the same processes as those in the first embodiment are performed to complete silicon carbide semiconductor device 40 according to the second embodiment.

As described above, according to the second embodiment, the ashing region is provided at the upper surface and the second side surface on the front electrode side of the polyimide film, and the second polyimide film in which the ashing region is not provided is provided at the first side surface (side surface relatively closer to the field insulating film) of the polyimide film. Thus, when the peeling advances, the adhesion between the polyimide film and the field insulating film is stronger than the adhesion between the polyimide film not subjected to ashing and the encapsulation resin. Therefore, the peeling advances to the surface of the second polyimide film without penetrating inside the semiconductor chip, and the peeling may be controlled to the outside of the semiconductor chip. Therefore, it is possible to prevent the semiconductor device from failing in terms of electrical characteristics due to peeling.

In each of the embodiments described above, for example, dimensions, dopant concentrations, and the like of the respective portions are variously set according to necessary specifications and the like. In addition, in the embodiments of the present disclosure, while a SBD and a trench MOSFET have been described as examples, the present disclosure is not limited hereto and is applicable to semiconductor devices having various configurations such as MOS semiconductor devices including planar MOSFETs and insulated gate bipolar transistors (IGBTs). Further, in each of the embodiments described above, while a case where silicon carbide is used as a semiconductor has been described as an example, the present disclosure is also applicable to semiconductors other than silicon carbide such as silicon (Si) and gallium nitride (GaN). Further, in the present disclosure, in each of the embodiments, while the first conductivity type is assumed to be an n-type and the second conductivity type is assumed to be a p-type, the present disclosure is similarly implemented when the first conductivity type is a p-type and the second conductivity type is an n-type.

According to the disclosure, when peeling advances, the adhesion between the polyimide film and the field insulating film is stronger than the adhesion between the polyimide film not subjected to ashing and the encapsulation resin. Therefore, the peeling advances to the first side surface (side surface relatively closer to the field insulating film) of the polyimide film without penetrating inside the semiconductor chip, and the peeling may be controlled to the outside of the semiconductor chip. Therefore, it is possible to prevent the semiconductor device from failing in terms of electrical characteristics due to peeling.

According to the semiconductor device and the method of manufacturing the semiconductor device according to the present disclosure, it is possible to prevent the progress of peeling between the encapsulation resin and the insulating film outside the chip and prevent a failure due to the peeling.

As described above, the semiconductor device and the method of manufacturing the semiconductor device according to the present disclosure are useful for power semiconductor devices used in power converting equipment such as inverters, power supply devices of various industrial machines, igniters of automobiles, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a semiconductor substrate having an active region and a termination region surrounding a periphery of the active region in a plan view;
a front electrode provided substantially in the active region;
a field insulating film provided in the termination region and adjacent to the front electrode to form a boundary portion therebetween; and
a first polyimide film covering the boundary portion between the front electrode and the field insulating film, the first polyimide film having
an upper surface,
a first side surface, and
a second side surface,
the first side surface being closer to the field insulating film than is the second side surface, the second side surface being closer to the front electrode than is the first side surface, a surface roughness of the first side surface being smaller than a surface roughness of the second side surface and a surface roughness of the upper surface of the first polyimide film.

2. The semiconductor device according to claim 1, wherein
the upper surface of the first polyimide film has
a first portion having a surface roughness thereof greater than that of the first side surface of the first polyimide film, and
a second portion having a surface roughness thereof smaller than that of the first portion, and
a boundary between the first portion and the second portion is closer to the first side surface of the first polyimide film than to the second side surface of the first polyimide film.

3. The semiconductor device according to claim 1, wherein the surface roughness of each of the second side surface and the upper surface of the first polyimide film is not less than 5 nm but not more than 60 nm.

4. The semiconductor device according to claim 1, wherein the surface roughness of the first side surface of the first polyimide film is greater than 0 nm but not more than 3 nm.

5. The semiconductor device according to claim 1, wherein a distance from the first side surface to the second side surface of the first polyimide film is not less than 100 μm but not more than 800 μm.

6. The semiconductor device according to claim 1, wherein the field insulating film has two layers including a layer of a thermal oxide film and a layer of a deposited insulating film.

7. The semiconductor device according to claim 1, further comprising a second polyimide film covering the first side surface of the first polyimide film, wherein
a surface roughness of the second polyimide film is smaller than the surface roughness of the upper surface of the first polyimide film.

8. The semiconductor device according to claim 1, wherein
the semiconductor substrate has a first surface and a second surface opposite to each other,
the semiconductor device further comprises:
a first semiconductor layer of a first conductivity type, provided at the first surface of the semiconductor substrate and having a dopant concentration lower than a dopant concentration of the semiconductor substrate, the first semiconductor layer having a first surface and a second surface opposite to each other, the second surface thereof facing the semiconductor substrate;
a plurality of first semiconductor regions of a second conductivity type, selectively provided in the first semiconductor layer, at the first surface thereof, in contact with the front electrode; and
a back electrode provided at the second surface of the semiconductor substrate.

9. The semiconductor device according to claim 1, wherein
the semiconductor substrate has a front surface and a back surface opposite to each other,
the semiconductor device further comprises:
a first semiconductor layer of a first conductivity type, provided at the front surface of the semiconductor substrate and having a dopant concentration lower than a dopant concentration of the semiconductor substrate, the first semiconductor layer having a first surface and a second surface opposite to each other, the second surface thereof facing the semiconductor substrate;
a second semiconductor layer of a second conductivity type, provided at the first surface of the first semiconductor layer and having a first surface and a second surface opposite to each other, the second surface thereof facing the semiconductor substrate;
a plurality of first semiconductor regions of the first conductivity type, selectively provided in the second semiconductor layer, at the first surface thereof;
a gate electrode provided on at least a part of the first surface of the second semiconductor layer, between the plurality of first semiconductor regions and the first semiconductor layer via a gate insulating film; and
a back electrode provided at the back surface of the semiconductor substrate, wherein
the front electrode is provided on surfaces of the second semiconductor layer and the plurality of first semiconductor regions.

10. A method of manufacturing a semiconductor device including a semiconductor substrate having an active region and a termination region surrounding a periphery of the active region in a plan view, the method comprising:
forming a field insulating film in the termination region;
forming a front electrode substantially in the active region and adjacent to the field insulating film to form a boundary therebetween;
forming a first polyimide film covering the boundary between the front electrode and the field insulating film, the first polyimide film having a first side surface and a second side surface opposite to each other, the first side surface being closer to the field insulating film than is the second side surface, and the second side surface being closer to the front electrode than is the first side surface; and
performing ashing for roughening a surface of the first polyimide film.

11. The method of manufacturing the semiconductor device according to claim 10, wherein the ashing is performed using oxygen plasma.

12. The method of manufacturing the semiconductor device according to claim 10, the method further comprising forming a second polyimide film covering the first side surface of the first polyimide film after performing the ashing.

13. The method of manufacturing the semiconductor device according to claim 12, wherein the second polyimide film is formed using a discharge method.

14. The method of manufacturing the semiconductor device according to claim 10, the method further comprising forming a resist covering the first side surface of the first polyimide film before performing the ashing.
